(19) United States
(12) Patent Application Publication
(10) Pub. No.: US 2025/0285879 A1
(43) Pub. Date: Sep. 11, 2025

(54) PROCESSING METHOD AND COMPUTER-READABLE STORAGE MEDIUM

(71) Applicant: DISCO CORORATION, Tokyo (JP)

(72) Inventor: Takezo SAKAGUCHI, Tokyo (JP)

(21) Appl. No.: 19/062,215

(22) Filed: Feb. 25, 2025

(30) Foreign Application Priority Data
Mar. 8, 2024 (JP) 2024-036210

(51) Int. Cl. H01L 21/322; B23K 26/53; B23K 101/40; H01L 21/304

(52) U.S. Cl. CPC H01L 21/3221; B23K 26/53; H01L 21/304; B23K 2101/40

(57) ABSTRACT

A processing method is a method of processing a workpiece including a base material and a device layer formed on the base material. The workpiece has a plurality of planned division lines. The device layer is formed by stacking a plurality of layers. The processing method includes: denaturing a specific layer constituting the device layer by applying a laser beam along the planned division lines of the workpiece via the base material; and after denaturing the specific layer, by applying a laser beam along the planned division lines, forming a modified layer along the planned division lines in the base material and forming a crack extending from the modified layer for dividing the device layer.

### CROSS-REFERENCE TO RELATED APPLICATION(S)

The present application claims priority to and incorporates by reference the entire contents of Japanese Patent Application No. 2024-036210 filed in Japan on Mar. 8, 2024.

### TECHNICAL FIELD

The present disclosure relates to a processing method of a workpiece having a base material and a device layer, and a computer-readable storage medium storing a laser beam processing program.

### BACKGROUND

For example, a processing method has been proposed, which uses a laser beam to divide a semiconductor wafer in which a device layer constituting devices is formed on a semiconductor base material (see, for example, JP 2005-86161 A).

In the processing method disclosed in JP 2005-86161 A, a modified layer is formed inside the semiconductor base material by applying a laser beam to the semiconductor wafer along streets while condensing the laser beam inside the semiconductor wafer, and cracks are formed to extend from the modified layer toward the surface of the semiconductor wafer.

However, in the processing method disclosed in JP 2005-86161 A, the cracks may not extend straight from the modified layer but extend obliquely, or may extend bifurcating from the modified layer, depending on the thickness, material, and the like of the device layer. In the case of such a division defect, chips formed by dividing the semiconductor wafer differ in the outer diameter size, and thus improvement has been desired.

### SUMMARY

A processing method according to the present disclosure is of processing a workpiece including a base material and a device layer formed on the base material. The workpiece has a plurality of planned division lines. The device layer is formed by stacking a plurality of layers. The processing method includes: denaturing a specific layer constituting the device layer by applying a laser beam along the planned division lines of the workpiece via the base material; and after denaturing the specific layer, by applying a laser beam along the planned division lines, forming a modified layer along the planned division lines in the base material and forming a crack extending from the modified layer for dividing the device layer.

A non-transitory computer readable storage medium according to the present disclosure stores a laser beam processing program for processing a workpiece including a base material and a device layer formed on the base material. The workpiece has a plurality of planned division lines. The device layer is formed by stacking a plurality of layers. The laser beam processing program causes a computer to execute: denaturing a specific layer constituting the device layer by applying a laser beam along the planned division lines of the workpiece via the base material; and after denaturing the specific layer, by applying a laser beam along the planned division lines, forming a modified layer in the base material along the planned division lines and forming a crack extending from the modified layer for dividing the device layer.

### BRIEF DESCRIPTION OF THE DRAWINGS

FIG. 1 is a perspective view illustrating a configuration example of a workpiece to be processed by a processing method according to an embodiment;

FIG. 2 is a cross-sectional view schematically illustrating main parts of the workpiece illustrated in FIG. 1;

FIG. 3 is a flowchart illustrating the flow of the processing method according to the embodiment;

FIG. 4 is a perspective view illustrating a configuration example of a laser beam processing machine that performs a specific layer denaturation step and a modification step of the processing method illustrated in FIG. 3;

FIG. 5 is a diagram illustrating the configuration of a laser beam application unit of the laser beam processing machine illustrated in FIG. 4;

FIG. 6 is a cross-sectional view schematically illustrating the main parts of the workpiece with a tape attached to its surface in the specific layer denaturation step of the processing method illustrated in FIG. 3;

FIG. 7 is a cross-sectional view of the workpiece schematically illustrating a state in which a laser beam is applied to the workpiece in the specific layer denaturation step of the processing method illustrated in FIG. 3;

FIG. 8 is a plan view of the workpiece schematically illustrating pulsed laser beam spots where the laser beam is applied to a specific layer illustrated in FIG. 7;

FIG. 9 is a cross-sectional view schematically illustrating the main parts of the workpiece during the modification step of the processing method illustrated in FIG. 3;

FIG. 10 is a cross-sectional view schematically illustrating the main parts of the workpiece after the modification step of the processing method illustrated in FIG. 3;

FIG. 11 is a perspective view schematically illustrating a grinding step of the processing method illustrated in FIG. 3; and

FIG. 12 is a cross-sectional view schematically illustrating the main parts of the workpiece after the grinding step of the processing method illustrated in FIG. 3.

### DETAILED DESCRIPTION

An embodiment of the present disclosure will be described in detail with reference to the drawings. The present invention is not limited by the contents described in the following embodiment. In addition, constituent elements described below include those that can be easily assumed by those skilled in the art and those that are substantially the same. Furthermore, configurations described below can be appropriately combined. In addition, various omissions, substitutions, or changes in the configurations can be made without departing from the gist of the present invention.

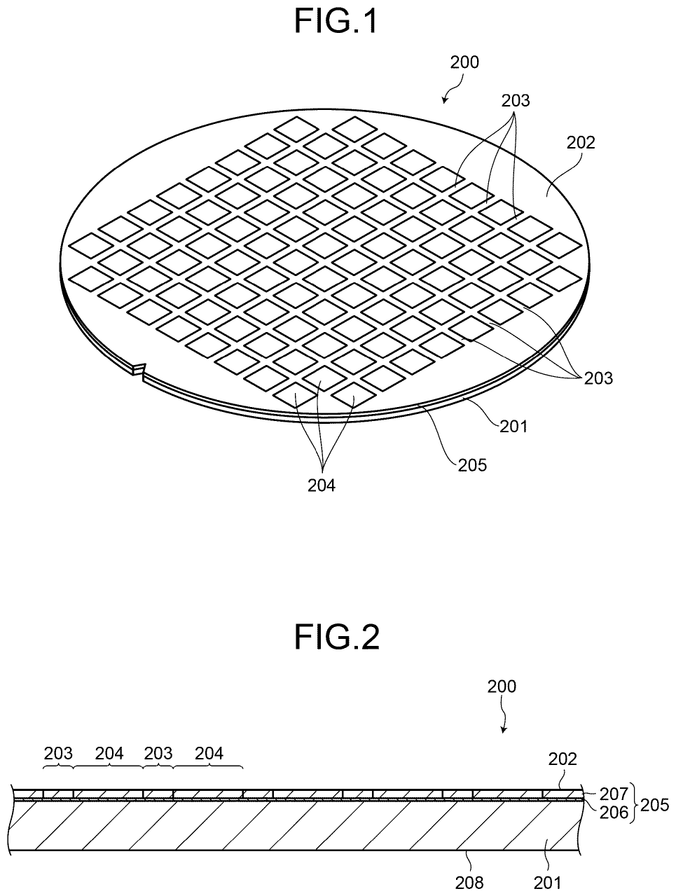

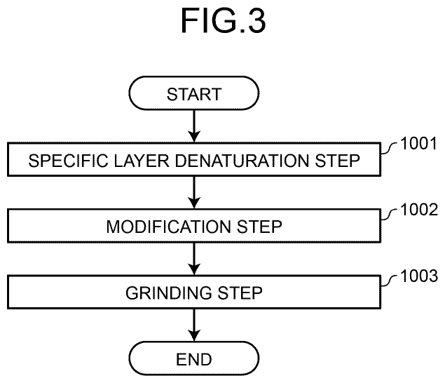

A processing method according to an embodiment of the present invention will be described with reference to the drawings. FIG. 1 is a perspective view illustrating a configuration example of a workpiece to be processed by the processing method according to the embodiment. FIG. 2 is a cross-sectional view schematically illustrating main parts of the workpiece illustrated in FIG. 1. FIG. 3 is a flowchart illustrating the flow of the processing method according to the embodiment.

### Workpiece

The processing method according to the embodiment is a processing method of a workpiece 200 illustrated in FIG. 1. As illustrated in FIG. 1, the workpiece 200 to be processed by the processing method according to the embodiment is a wafer, for example, a disk-shaped semiconductor wafer using silicon, sapphire, gallium, SiC, or the like as a base material 201, or an optical device wafer. As illustrated in FIG. 1, the workpiece 200 includes devices 204 formed at respective areas on a front surface 202, which are sectioned in a lattice pattern by planned division lines 203 intersecting each other. The devices 204 are, for example, integrated circuits (IC), large scale integration (LSI) integrated circuits, or memories (semiconductor storage devices). In this manner, the plurality of planned division lines 203 are set on the workpiece 200.

As illustrated in FIGS. 1 and 2, the workpiece 200 includes the base material 201 and a device layer 205 formed on the base material 201. The device layer 205 includes a specific layer 206 formed on the base material 201 and a functional layer 207 formed on the specific layer 206. In the embodiment, the specific layer 206 is a metal layer made of a metal that is a ductile material. The functional layer 207 includes: low dielectric constant insulator films (hereinafter, referred to as low-k films) made of a film of an inorganic material such as SiOF or BSG (SiOB), a film of an organic material such as a polyimide-based or parylene-based polymer, or carbon-containing silicon oxide (SiOCH); and a circuit layer including a conductive metal pattern and a metal film.

The low-k films, together with the circuit layer, are stacked to form the devices 204. The circuit layer constitutes the circuits of the devices 204. Thus, the devices 204 are constituted by: the low-k films stacked on each other of the functional layer 207 formed on the specific layer 206 on the base material 201; and the circuit layer situated between the low-k films. At areas of the planned division lines 203, the device layer 205 is constituted by: the specific layer 206; and the low-k films stacked on the specific layer 206 except for an area of a test elementary group (TEG). As described above, the device layer 205 includes the specific layer 206 at least at areas overlapping the planned division lines 203, and is formed by stacking a plurality of layers.

In the present invention, the material of the base material 201 of the workpiece 200 and the type of the devices 204 are not limited to those described in the embodiment. In the present invention, the specific layer 206 is not limited to a metal layer made of a metal, and may be a resin layer made of a resin that is a ductile material. If the specific layer 206 is a resin layer, it is desirable that the specific layer 206 be an insulator layer made of a polymer-based insulator which is a resin. In addition, the specific layer 206 is not limited to a layer interposed between the base material 201 and the functional layer 207, and may be a layer in the functional layer 207.

### Processing Method

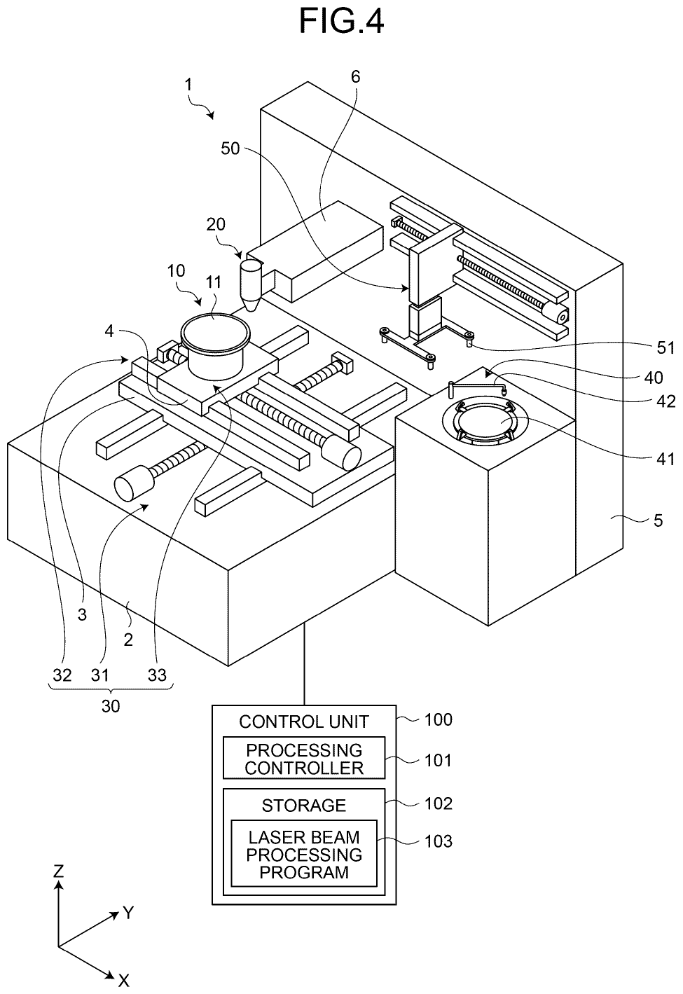

Next, the processing method according to the embodiment will be described. As illustrated in FIG. 3, the processing method according to the embodiment includes a specific layer denaturation step 1001, a modification step 1002, and a grinding step 1003. The specific layer denaturation step 1001 and the modification step 1002 are performed by a laser beam processing machine 1 illustrated in FIG. 4.

### Laser Beam Processing Machine

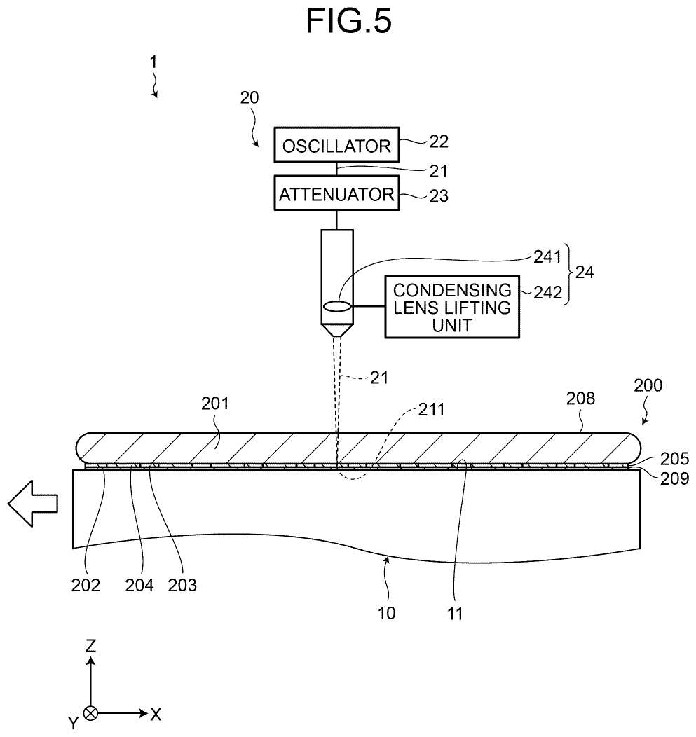

Next, the laser beam processing machine 1 illustrated in FIG. 4 will be described. FIG. 4 is a perspective view illustrating a configuration example of the laser beam processing machine that performs the specific layer denaturation step and the modification step of the processing method illustrated in FIG. 3. FIG. 5 is a diagram illustrating the configuration of a laser beam application unit of the laser beam processing machine illustrated in FIG. 4. As illustrated in FIG. 4, the laser beam processing machine 1 includes a holding unit 10, a moving unit 30, a laser beam application unit 20, an image pick-up unit (not illustrated), a cleaning unit 40, a conveyance unit 50, and a control unit 100.

The holding unit 10 includes a holding surface 11 that is disk-shaped. The holding surface 11 is flat in the horizontal direction in which the workpiece 200 is held, and is formed of porous ceramic or the like. In addition, the holding unit 10 is provided to be movable by the moving unit 30 over a processing area under the laser beam application unit 20, and a loading/unloading area which is separated from the area under the laser beam application unit 20 and where the workpiece 200 is loaded and unloaded.

The holding unit 10 is connected to a vacuum suction source (not illustrated), and sucks and holds the workpiece 200 placed on the holding surface 11 by being sucked by the vacuum suction source. In the embodiment, the holding unit 10 sucks and holds the front surface 202 side of the workpiece 200 via a tape 209 attached to the front surface 202 of the workpiece 200.

The moving unit 30 relatively moves the holding unit 10 and the laser beam application unit 20. The moving unit 30 includes at least: a Y-axis moving unit 31 which is an indexing-feed unit that moves the holding unit 10 in a Y-axis direction parallel to the horizontal direction; an X-axis moving unit 32 which is a processing-feed unit that moves the holding unit 10 in an X-axis direction parallel to the horizontal direction and orthogonal to the Y-axis direction; and a rotational moving unit 33 that rotates the holding unit 10 about a central axis parallel to a Z-axis direction parallel to the vertical direction.

The Y-axis moving unit 31 is placed on a machine body 2, and moves the holding unit 10 in the Y-axis direction by moving a moving plate 3 on which the X-axis moving unit 32 is placed in the Y-axis direction. The X-axis moving unit 32 is placed on the moving plate 3, and moves the holding unit 10 in the X-axis direction by moving a second moving plate 4 on which the rotational moving unit 33 is placed in the X-axis direction. The rotational moving unit 33 is placed on the second moving plate 4 and supports the holding unit 10, thereby rotating the holding unit 10 about the central axis.

The Y-axis moving unit 31 moves the moving plate 3 in the Y-axis direction, together with the X-axis moving unit 32, the second moving plate 4, the rotational moving unit 33, and the holding unit 10. The X-axis moving unit 32 moves the second moving plate 4 in the X-axis direction, together with the rotational moving unit 33 and the holding unit 10.

The Y-axis moving unit 31 and the X-axis moving unit 32 include a known ball screw provided to be rotatable about a central axis, a known motor that rotates the ball screw about the central axis, and a known guide rail that supports the moving plates 3 and 4 such that they are movable in the X-axis direction or the Y-axis direction. The rotational moving unit 33 includes a known motor or the like that rotates the holding unit 10 about the central axis.

As illustrated in FIG. 4, a portion of the laser beam application unit 20 is provided at the distal end of a support column 6 whose proximal end portion is supported by an upright wall 5 erected from an end of the machine body 2 in the Y-axis direction. The laser beam application unit 20 applies a laser beam 21 (illustrated in FIG. 5) to the workpiece 200 held by the holding unit 10 to perform laser beam processing.

As illustrated in FIG. 5, the laser beam application unit 20 includes an oscillator 22, an attenuator 23 which is an output adjustment unit, and a condensing unit 24. The oscillator 22 is a device that generates and oscillates the pulsed laser beam 21 with a wavelength capable of passing through the workpiece 200.

The attenuator 23 adjusts the output of the laser beam 21 oscillated by the oscillator 22. The condensing unit 24 includes a condensing lens 241 that condenses the laser beam 21 generated and oscillated by the oscillator 22 on the workpiece 200 held by the holding unit 10, and a condensing lens lifting unit 242 that moves the condensing lens 241 up and down in the Z-axis direction to move a focal point 211 of the laser beam 21 up and down in the Z-axis direction.

The image pick-up unit includes an image pick-up device that takes an image of an area to be divided of the workpiece 200 held by the holding unit 10 before laser beam processing. The image pick-up device is, for example, a charge-coupled device (CCD) image pick-up device or a complementary MOS (CMOS) image pick-up device. The image pick-up unit takes an image of the workpiece 200 held by the holding unit 10, obtains an image for performing alignment for aligning the workpiece 200 and the laser beam application unit 20, and outputs the obtained image to the control unit 100.

The cleaning unit 40 cleans the workpiece 200 after laser beam processing. The cleaning unit 40 includes a spinner table 41 with a holding surface that is disk-shaped, and a cleaning nozzle 42. The holding surface is flat in the horizontal direction in which the workpiece 200 is held, and is formed of porous ceramic or the like. The spinner table 41 is rotated about a central axis parallel to the Z-axis direction by a rotary drive source (not illustrated).

The spinner table 41 sucks and holds the workpiece 200 placed on the holding surface with the holding surface connected to a vacuum suction source (not illustrated) and sucked by the vacuum suction source. In the embodiment, the spinner table 41 sucks and holds the front surface 202 side of the workpiece 200 via a tape 209.

The cleaning nozzle 42 supplies cleaning water (in the embodiment, pure water) to the front surface 202 of the workpiece 200 held by the spinner table 41, and cleans a back surface 208 on the back side of the front surface 202 of the workpiece 200.

The conveyance unit 50 conveys the workpiece 200 between the holding unit 10 and the cleaning unit 40. The conveyance unit 50 includes conveyance arms 51 that convey the workpiece 200 between the holding unit 10 and the cleaning unit 40.

The control unit 100 controls each constituent element of the laser beam processing machine 1 to cause the laser beam processing machine 1 to perform a processing operation on the workpiece 200. The control unit 100 is a computer including an arithmetic processing device including a microprocessor such as a central processing unit (CPU), a storage device including a memory such as a read only memory (ROM) or a random access memory (RAM), and an input/output interface device. The arithmetic processing device of the control unit 100 performs arithmetic processing according to a computer program stored in the storage device, and outputs a control signal for controlling the laser beam processing machine 1 to each constituent element of the laser beam processing machine 1 via the input/output interface device.

The control unit 100 is connected to a display unit (not illustrated) including a liquid crystal display device or the like that displays a state, an image, or the like of the processing operation, and an input unit (not illustrated) used when an operator registers processing content information or the like. The input unit includes at least one of a touch panel provided on the display unit and an external input device such as a keyboard.

As illustrated in FIG. 1, the control unit 100 includes a processing controller 101 and a storage 102. The processing controller 101 controls each constituent element of the laser beam processing machine 1 to cause the laser beam processing machine 1 to perform the processing operation on the workpiece 200.

The storage 102 stores a laser beam processing program 103. The laser beam processing program 103 is a computer program that causes the control unit 100, which is a computer, that is, the laser beam processing machine 1 to perform the specific layer denaturation step 1001 and the modification step 1002 to perform laser beam processing on the workpiece 200.

The function of the storage 102 is implemented by the storage device described above. The function of the processing controller 101 is implemented by the arithmetic processing device described above performing arithmetic processing according to a computer program stored in the storage device.

### Specific Layer Denaturation Step

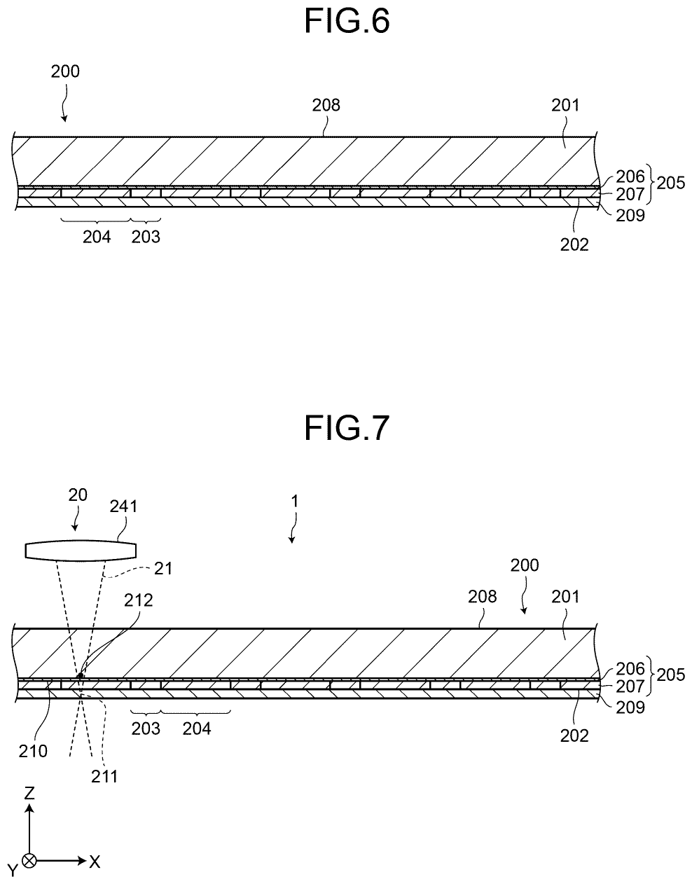

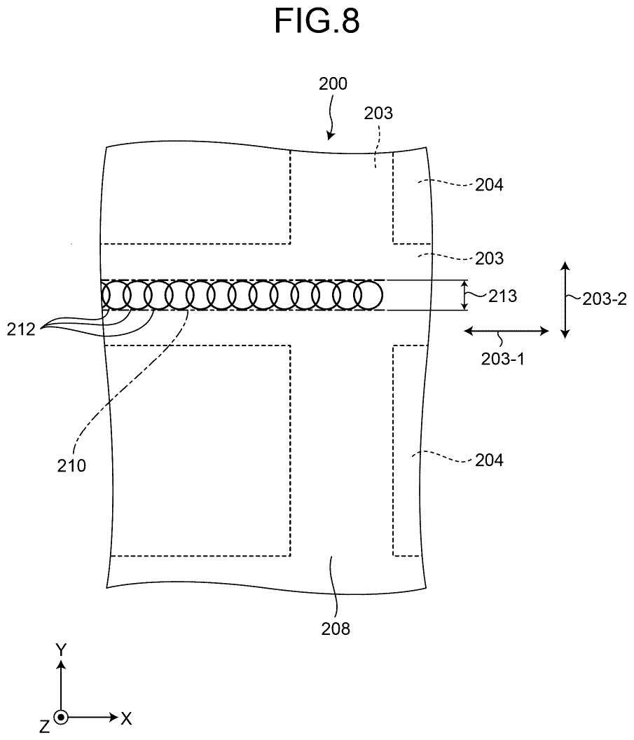

Next, the specific layer denaturation step 1001 will be described. FIG. 6 is a cross-sectional view schematically illustrating the main parts of the workpiece with the tape attached to its surface in the specific layer denaturation step of the processing method illustrated in FIG. 3. FIG. 7 is a cross-sectional view of the workpiece schematically illustrating a state in which a laser beam is applied to the workpiece in the specific layer denaturation step of the processing method illustrated in FIG. 3. FIG. 8 is a plan view of the workpiece schematically illustrating pulsed laser beam spots where the laser beam is applied to the specific layer illustrated in FIG. 7.

The specific layer denaturation step 1001 is a step of denaturing the specific layer 206 by applying the laser beam 21 to the specific layer 206 along the planned division lines 203 of the workpiece 200 via the base material 201. First, in the specific layer denaturation step 1001 of the embodiment, the disk-shaped tape 209 equal in diameter to the workpiece 200 is attached to the front surface 202 of the workpiece 200 as illustrated in FIG. 6. In the specific layer denaturation step 1001 of the embodiment, the laser beam processing machine 1 starts the processing operation, that is, the execution of the laser beam processing program 103, and starts the specific layer denaturation step 1001, when an operator or the like registers processing conditions in the control unit 100, the front surface 202 side of the workpiece 200 is placed on the holding surface 11 of the holding unit 10 via the tape 209, and the control unit 100 receives an instruction to start the processing operation from the operator or the like.

The processing conditions include the repetition frequency of the pulsed laser beam 21, the output of the laser beam 21, the relative movement rates (referred to as processing-feed rates) in the X-axis direction of the laser beam application unit 20 and the holding unit 10, the position in the thickness direction of the workpiece 200 of the focal point 211 (illustrated in FIG. 5 and the like) of the laser beam 21, and the like, in the specific layer denaturation step 1001 and the modification step 1002.

In the specific layer denaturation step 1001 of the embodiment, the processing controller 101 of the control unit 100 of the laser beam processing machine 1 according to the embodiment sucks and holds the front surface 202 side of the workpiece 200 on the holding surface 11 of the holding unit 10 via the tape 209. In the specific layer denaturation step 1001 of the embodiment, the processing controller 101 of the control unit 100 of the laser beam processing machine 1 controls the moving unit 30 to move the holding unit 10 toward the processing area, takes an image of the workpiece 200 by the image pick-up unit, and performs alignment based on the image taken by the image pick-up unit. In the present invention, the image pick-up unit may be, for example, an infrared camera, and alignment may be performed based on an image taken from the back surface 208 side of the workpiece 200 by the infrared camera, which is the image pick-up unit. At least part of the holding surface 11 of the holding unit 10 may be made of a transparent member, and the alignment may be performed by taking an image from the front surface 202 side of the workpiece 200 via the transparent member.

In the specific layer denaturation step 1001 of the embodiment, as illustrated in FIG. 7, the processing controller 101 of the control unit 100 of the laser beam processing machine 1 sets the focal point 211 of the laser beam 21 inside the tape 209, and applies the laser beam 21 to the center in the width direction of the planned division lines 203 of the workpiece 200 from the back surface 208 side while controlling the laser beam application unit 20 and the moving unit 30 to relatively move the condensing unit 24 of the laser beam application unit 20 and the holding unit 10 in the X-axis direction along the planned division lines 203. As described above, in the specific layer denaturation step 1001 of the embodiment, the laser beam processing machine 1 applies the laser beam 21 while positioning the focal point 211 of the laser beam 21 at a position different from the specific layer 206.

In this way, in the specific layer denaturation step 1001 of the embodiment, the laser beam processing machine 1 performs so-called defocusing to apply the laser beam 21 to the specific layer 206, and as illustrated in FIG. 8, expands the diameter of pulsed laser beam spots 212 in the specific layer 206 to be larger than that of the focal point 211. Further, in the specific layer denaturation step 1001 of the embodiment, the laser beam processing machine 1 expands the diameter of the pulsed laser beam spots 212 in the specific layer 206 to be larger than that of the focal point 211, and as illustrated in FIG. 8, applies the laser beam 21 to an area of the specific layer 206 having a predetermined width 213 in a direction 203-2 orthogonal to an extending direction 203-1 of the planned division line 203 to which the laser beam 21 is applied.

In the specific layer denaturation step 1001 of the embodiment, in the laser beam processing machine 1, a processing-feed rate and a repetition frequency is set such that the pulsed laser beam spots 212 in the specific layer 206 partially overlap each other. As described above, in the specific layer denaturation step 1001 of the embodiment, the pulsed laser beam 21 is applied along the planned division lines 203, such that the pulsed laser beam spot 212 where one pulsed laser beam 21 is applied to the specific layer 206 and the pulsed laser beam spot 212 where the next pulsed laser beam 21 is applied to the specific layer 206 partially overlap each other. In addition, in the specific layer denaturation step 1001 of the embodiment, in the laser beam processing machine 1, the output of the laser beam 21 is set to a value that does not exceed a processing threshold value of the base material 201 (in the embodiment, a value of approximately 1/10 of the output in the modification step 1002) in a state where the focal point 211 is set at the above-described position. Thus, the laser beam processing machine 1 does not process the base material 201.

In the specific layer denaturation step 1001 of the embodiment, the condensing lens 241 performs so-called defocusing of the laser beam 21 for the specific layer 206. Alternatively, in the present invention, a beam expander or a spatial light modulator may expands the diameter of the pulsed laser beam spots 212 of the laser beam 21 generated by the oscillator 22 for the specific layer 206, instead of the defocusing. In the specific layer denaturation step 1001 of the present invention, the pulsed laser beam spots 212 on the specific layer 206 may not partially overlap each other, and a laser beam of a continuous wave (CW) may be applied instead of the pulsed laser beam 21.

In the specific layer denaturation step 1001 of the embodiment, the laser beam processing machine 1 applies the defocused laser beam 21 to the specific layer 206 of all the planned division lines 203, heats and denatures the specific layer 206 along the planned division lines 203, and forms a denatured portion 210 in the specific layer 206. The denatured portion 210 has mechanical strength lower than that of the other specific layer 206, and is more easily divided than the other specific layer 206 by an external force. In the specific layer denaturation step 1001 of the embodiment, the laser beam processing machine 1 forms the denatured portion 210 in the specific layer 206 along all the planned division lines 203.

### Modification Step

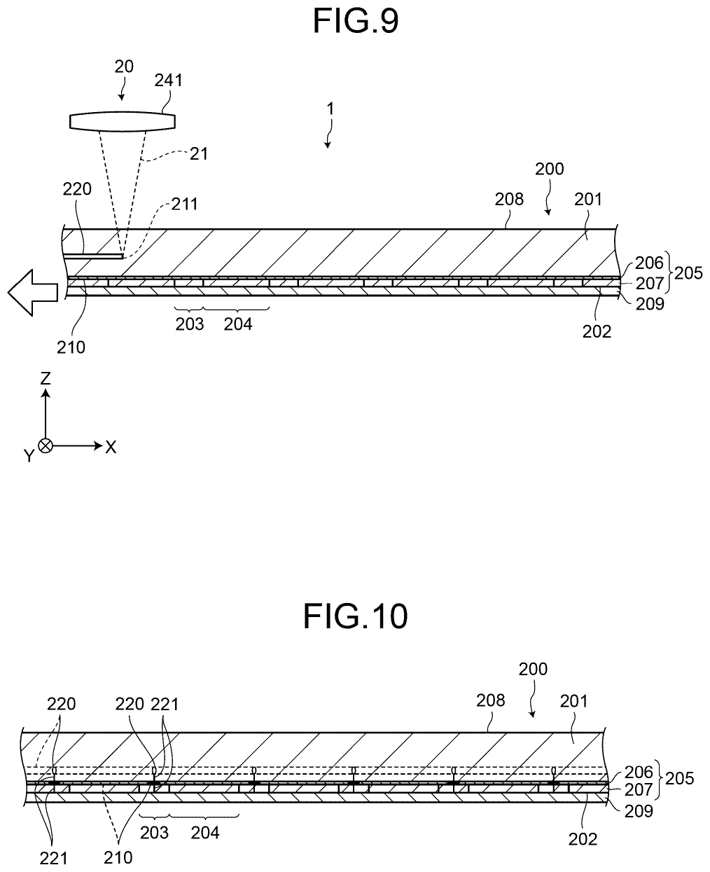

Next, the modification step 1002 will be described. FIG. 9 is a cross-sectional view schematically illustrating the main parts of the workpiece during the modification step of the processing method illustrated in FIG. 3. FIG. 10 is a cross-sectional view schematically illustrating the main parts of the workpiece after the modification step of the processing method illustrated in FIG. 3. The modification step 1002 is a step of forming a modified layer 220 along the planned division lines 203 in the base material 201 and forming cracks 221 extending from the modified layer 220 for dividing the device layer 205, by applying the laser beam 21 along the planned division lines 203 after performing the specific layer denaturation step 1001.

The modified layer 220 means an area where density, a refractive index, mechanical strength, and other physical characteristics are different from those of the surrounding area, and examples thereof include a molten processed area, a crack area, a dielectric breakdown area, a refractive index change area, and an area where these areas are mixed. Furthermore, the mechanical strength and the like of the modified layer 220 are lower than those of the other portions of the base material 201 of the workpiece 200.

In the modification step 1002 of the embodiment, as illustrated in FIG. 9, the processing controller 101 of the control unit 100 of the laser beam processing machine 1 sets the focal point 211 of the laser beam 21 inside the base material 201, and applies the laser beam 21 to the center in the width direction of the planned division lines 203 of the workpiece 200 from the back surface 208 side while controlling the laser beam application unit 20 and the moving unit 30 to relatively move the condensing unit 24 of the laser beam application unit 20 and the holding unit 10 in the X-axis direction along the planned division lines 203. In the modification step 1002 of the embodiment, in order for the laser beam 21 to have a wavelength capable of passing through the base material 201 of the workpiece 200, the modified layer 220 is formed inside the base material 201 along the planned division lines 203, and the cracks 221 are formed to extend from the modified layer 220 toward the denatured portion 210 and extend from the denatured portion 210 toward the front surface 202, as illustrated in FIG. 10.

In this way, in the modification step 1002, the cracks 221 that divide the device layer 205 is formed. In the modification step 1002 of the embodiment, in the laser beam processing machine 1, the output of the laser beam 21 is set to a value that exceeds the processing threshold value of the base material 201 (in the embodiment, a value of approximately 10 times of the output in the specific layer denaturation step 1001) in a state where the focal point 211 is set at the above-described position. Thus, the laser beam processing machine 1 forms the modified layer 220 inside the base material 201.

In the embodiment, the laser beam 21 generated by the same oscillator 22 is used in both the specific layer denaturation step 1001 and the modification step 1002. However, the present invention is not limited to this, and laser beams 21 generated by different oscillators 22 may be used in the specific layer denaturation step 1001 and the modification step 1002. In the modification step 1002 of the embodiment, the laser beam processing machine 1 forms the modified layer 220 and the cracks 221 inside the workpiece 200 along all the planned division lines 203.

In the modification step 1002 of the embodiment, the modified layer 220 and the cracks 221 are formed inside the workpiece 200 along all the planned division lines 203, and then, the processing controller 101 of the control unit 100 of the laser beam processing machine 1 controls the moving unit 30 and the like to move the holding unit 10 to the loading/unloading area, and stops suction and holding on the holding surface 11 of the holding unit 10 in the loading/unloading area.

In the modification step 1002 of the embodiment, the processing controller 101 of the control unit 100 of the laser beam processing machine 1 controls the conveyance unit 50 to place the workpiece 200 from the holding unit 10 onto the holding surface of the spinner table 41 of the cleaning unit 40. In the modification step 1002 of the embodiment, the processing controller 101 of the control unit 100 of the laser beam processing machine 1 sucks and holds the front surface 202 side of the workpiece 200 on the holding surface of the spinner table 41 via the tape 209 to rotate the spinner table 41 about the central axis, and drops liquid cleaning water from the cleaning nozzle 42 to the center on the back surface 208 side of the workpiece 200.

The dropped cleaning water flows from the center side toward the outer peripheral side on the back surface 208 of the workpiece 200 due to centrifugal force generated by the rotation of the spinner table 41, and cleans the back surface 208 of the workpiece 200. In the modification step 1002 of the embodiment, the laser beam processing machine 1 supplies cleaning water for a predetermined period of time while rotating the spinner table 41 about the central axis, and cleans the back surface 208 of the workpiece 200. Note that in the present invention, the workpiece 200 may not be cleaned in the modification step 1002.

### Grinding Step

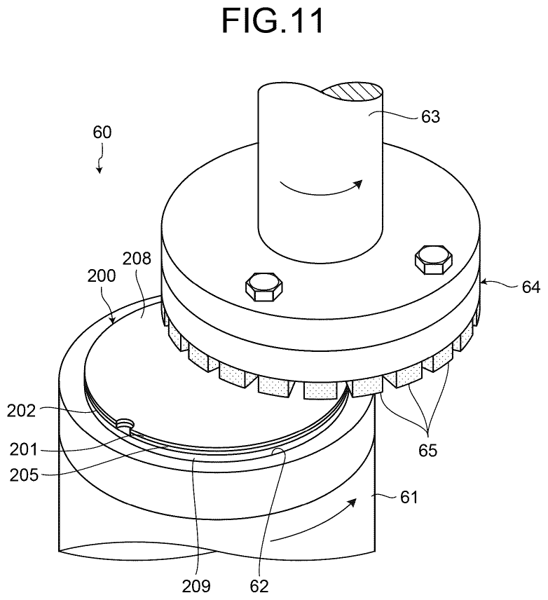

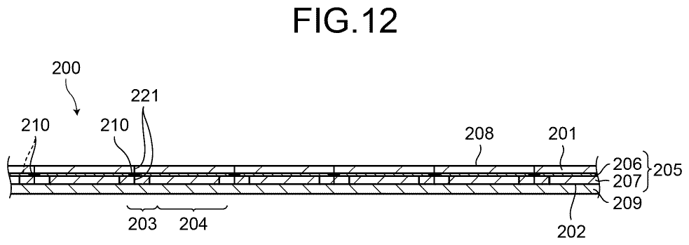

Next, the grinding step 1003 will be described. FIG. 11 is a perspective view schematically illustrating the grinding step of the processing method illustrated in FIG. 3. FIG. 12 is a cross-sectional view schematically illustrating the main parts of the workpiece after the grinding step of the processing method illustrated in FIG. 3. The grinding step 1003 is a step of grinding and thinning the base material 201 of the workpiece 200.

In the grinding step 1003 of the embodiment, a grinding machine 60 illustrated in FIG. 11 sucks and holds the front surface 202 side of the workpiece 200 on a holding surface 62 of a holding table 61 via the tape 209. In the grinding step 1003 of the embodiment, the grinding machine 60 supplies grinding water while rotating a grinding wheel 64 about a central axis by a spindle 63 and rotating the holding table 61 about a central axis thereof, and causes a grinding whetstone 65 to abut on the back surface 208 of the workpiece 200 and to approach the holding table 61 at a predetermined feeding rate, thereby grinding the back surface 208 of the workpiece 200 by the grinding whetstone 65, as illustrated in FIG. 11.

Then, in the grinding step 1003 of the embodiment, since the modified layer 220 and the cracks 221 are formed inside the workpiece 200 as illustrated in FIG. 12, the device layer 205 is divided into the individual devices 204 along the planned division lines 203, with the modified layer 220 and the cracks 221 as the starting points, due to grinding stress acting from the grinding wheel 64. In the grinding step 1003 of the embodiment, the grinding machine 60 grinds the back surface 208 of the workpiece 200 until the workpiece 200 has a predetermined thickness.

As described above, according to the processing method and the laser beam processing program 103 according to the embodiment, the laser beam 21 is applied to the specific layer 206 included in the device layer 205 to form the denatured portion 210 by denaturing a part of the specific layer 206 in the specific layer denaturation step 1001, before forming the modified layer 220 in the base material 201 in the modification step 1002. According to the processing method and the laser beam processing program 103 according to the embodiment, after forming the denatured portion 210 by denaturing part of the specific layer 206 in the specific layer denaturation step 1001, the modified layer 220 is formed in the base material 201, and the cracks 221 extending from the modified layer 220 for dividing the device layer 205 is formed in the modification step 1002.

As a result, according to the processing method and the laser beam processing program 103 according to the embodiment, the denatured portion 210 is formed in the specific layer 206, whereby the cracks 221 from the modified layer 220 extend straight in the thickness direction and divide the device layer 205. This provides the effect of reducing a division defect of the workpiece 200.

The present invention has an effect in that it is possible to reduce a division defect.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A processing method of a workpiece comprising a base material and a device layer formed on the base material, the workpiece having a plurality of planned division lines,
the device layer being formed by stacking a plurality of layers,
the processing method comprising:
denaturing a specific layer constituting the device layer by applying a laser beam along the planned division lines of the workpiece via the base material; and
after denaturing the specific layer, by applying a laser beam along the planned division lines, forming a modified layer along the planned division lines in the base material and forming a crack extending from the modified layer for dividing the device layer.

2. The processing method according to claim 1, wherein
denaturing the specific layer includes applying the laser beam to an area of the specific layer having a predetermined width in a direction orthogonal to an extending direction of the planned division line.

3. The processing method according to claim 2, wherein
denaturing the specific layer includes applying the laser beam while positioning a focal point of the laser beam at a position different from the specific layer.

4. The processing method according to claim 2, wherein
denaturing the specific layer includes applying a pulsed laser beam along the planned division lines, and the pulsed laser beam is applied such that a pulsed laser beam spot where one pulsed laser beam is applied to the specific layer and a pulsed laser beam spot where a next pulsed laser beam is applied to the specific layer partially overlap each other.

5. The processing method according to claim 1, further comprising grinding and thinning the base material after forming the modified layer and forming the crack.

6. A non-transitory computer readable storage medium storing a laser beam processing program for processing a workpiece comprising a base material and a device layer formed on the base material, the workpiece having a plurality of planned division lines,
the device layer being formed by stacking a plurality of layers,
the laser beam processing program causing a computer to execute:
denaturing a specific layer constituting the device layer by applying a laser beam along the planned division lines of the workpiece via the base material; and
after denaturing the specific layer, by applying a laser beam along the planned division lines, forming a modified layer in the base material along the planned division lines and forming a crack extending from the modified layer for dividing the device layer.
